(19) United States
(12) Patent Application Publication
(10) Pub. No.: US 2026/0344391 A1
(43) Pub. Date: Oct. 29, 2026

(54) THROUGH SUBSTRATE VIA WITH SPACED SHALLOW TRENCH ISOLATION

(71) Applicant: Taiwan Semiconductor Manufacturing Company, Ltd., Hsinchu (TW)

(72) Inventors: Yu-Chun Chen, Tainan City (TW); Wei-Cheng Hsu, Kaohsiung City (TW); Kuan-Chieh Huang, Hsinchu City (TW); Hung-Ling Shih, Tainan City (TW); Chen-Jong Wang, Hsin-Chu (TW); Dun-Nian Yaung, Taipei City (TW)

(21) Appl. No.: 19/735,596

(22) Filed: Jul. 9, 2026

Related U.S. Application Data
(62) Division of application No. 18/400,104, filed on Dec. 29, 2023.

(51) Int. Cl. H10W 20/20; H10W 10/00; H10W 10/17; H10W 20/00

(52) U.S. Cl. CPC H10W 20/20; H10W 10/014; H10W 10/17; H10W 20/023

(57) ABSTRACT

Some embodiments relate to an integrated device, including a substrate having a first side and a second side opposite the first side, the substrate being a first material; a first wire level on the first side of the substrate and having a first wire; a second wire level on the second side of the substrate and having a second wire; a through-substrate via (TSV) extending from the first wire to the second wire through the substrate; a shallow trench isolation (STI) region surrounding the TSV at the second side of the substrate; and a semiconductor region between the STI region and the TSV, the semiconductor region comprising the first material.

### REFERENCE TO RELATED APPLICATION

This Application is a Divisional of U.S. application Ser. No. 18/400,104, filed on Dec. 29, 2023, the contents of which are hereby incorporated by reference in their entirety.

### BACKGROUND

Vias are an integrated circuit component used to couple different wire levels together. Using vias, three dimensional circuits can be made, reducing the area of individual packages. Another advancement in reducing the form factor of devices are through-substrate vias (TSVs). TSVs extend through a substrate to couple wire levels that are formed on different sides of the substrate. The use of TSVs results in increased area on which to make front-end-of-line (FEOL) devices. TSVs further increase the flexibility of multi-chip devices, where integrated circuits can be formed on different chips that are subsequently bonded together.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate a cross-sectional view and a top view of some embodiments of a TSV with a shallow trench isolation (STI) region surrounding and spaced from the TSV.

FIG. 2 illustrates a cross-sectional view of additional embodiments of a TSV with an STI region surrounding and spaced from the TSV.

FIGS. 3A-3B illustrate top views of additional embodiments of a TSV with an STI region surrounding and spaced from the TSV, where a semiconductor region between the STI region and the TSV has various shapes when viewed from a top view.

FIGS. 4A-4B illustrate a cross-sectional view and a top view of additional embodiments of a TSV with an STI region surrounding and spaced from the TSV, where multiple TSVs extend through the STI region.

FIGS. 5-14 illustrate a series of cross-sectional views of some embodiments of a method of forming a TSV with an STI region surrounding and spaced from the TSV.

FIG. 15 illustrates a flowchart of some embodiments of a method of forming a TSV with an STI region surrounding and spaced from the TSV.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A through substrate via (TSV) is a conductive via that extends from a first side to a second side of a substrate. TSVs are used to couple devices and interconnect structures on the first side of the substrate to devices and interconnect structures on the second side of the substrate. This connection results in a larger integrated circuit being formable on the substrate, increasing the possible size and complexity of integrated circuits on the substrate. The TSV in some embodiments is also thermally conductive, resulting in the transfer of heat away from semiconductor devices and throughout the device, reducing the potential for heat to damage the connected devices.

Before forming the TSV, a variety of semiconductor devices may be formed on a first side and a second side of the substrate. The use of silicidation processes and stressing the channels of semiconductor devices may improve the performance of the semiconductor devices, and entail the use of a resist protective oxide (RPO) and a contact etch stop layer (CESL) on the second side of the substrate. Further, in some cases there are one or more layers on the first side of the substrate, including a layer comprising a high-κ material. Some methods of forming the TSV use multiple etching steps to expose an underlying wire. In some embodiments, the first etching step etches through the substrate to a shallow trench isolation (STI) region. The STI region insulates surrounding devices and doped wells from the TSV. The second etching step then etches through the STI region, the RPO, the CESL, and an interlayer dielectric (ILD) to reach the underlying layer. During the first etch, the high-κ layer is etched through.

The high-κ layer may comprise a polymer, such that the first etch results in a polymer residue building up on the inner sidewalls of the substrate and the one or more passivation layers. If a copper seed tool used to begin the formation of the TSV is exposed to the polymer residue, the polymer residue will contaminate the copper seed tool, leading to damage to the tool and increased production costs. A first insulative layer is formed over the polymer residue to prevent exposure of the copper seed tool to the polymer residue. A second insulative layer is further formed over the first insulative layer, and acts as a hard mask for the second etching step.

However, the second etching step, due to etching through the STI region, the RPO, the CESL, and the ILD, has a process time long enough that the second etching step also etches through the first insulative layer and second insulative layer. Etching through the first insulative layer and second insulative layer exposes the polymer residue, which contaminates the copper seed tool. Therefore, a method of reducing the process time of the second etch without fully removing the previously described layers is desirable.

The present disclosure provides a TSV extending through a semiconductor region between inner sidewalls of an STI region. The STI region is defined to have a first opening where the TSV will extend through the semiconductor region. The first opening is filled by a semiconductor region and is between inner sidewalls of the STI region. The first etch results in an opening extending from a first side of the substrate to the RPO on the second side of the substrate through the semiconductor region. The second etch then etches through a portion of the first insulative layer at the bottom of the substrate, the RPO, the CESL, and the ILD. Removing the portion of the STI region directly in the path of the second etch reduces the process time of the second etch, resulting in the first insulative layer continuing to cover the polymer residue. The first insulative layer continuing to cover the polymer residue prevents the polymer residue from contaminating the seed layer tool or other deposition tools.

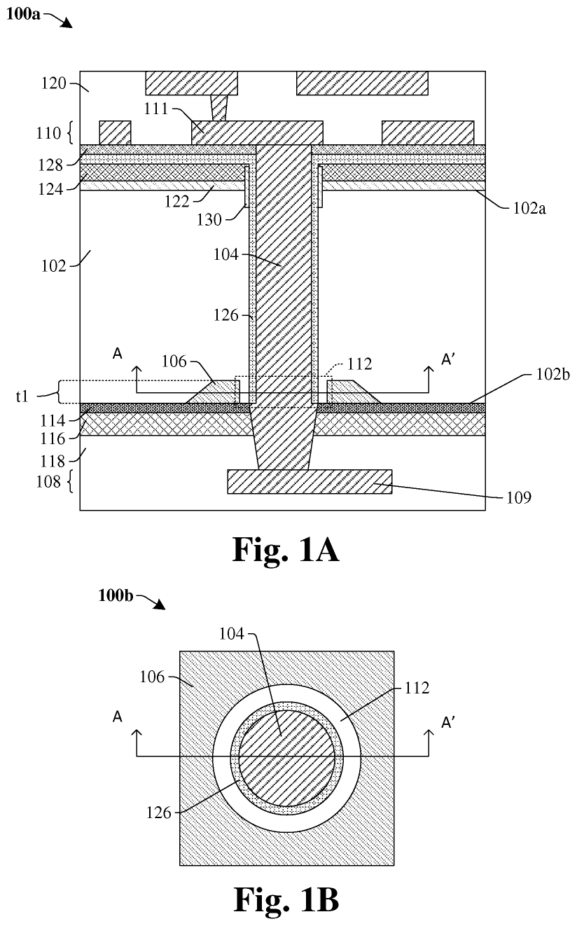

FIGS. 1A-1B illustrate a cross-sectional view 100a and a top view 100b of some embodiments of a TSV with a shallow trench isolation (STI) region surrounding and spaced from the TSV. The cross-sectional view 100a of FIG. 1A may, for example, be taken along line A-A′ in FIG. 1B.

As shown in the cross-sectional view 100a of FIG. 1A, a TSV 104 extends through a substrate 102. The TSV 104 extends from a first side 102a to a second side 102b of the substrate 102. The TSV 104 is continuously surrounded by an STI region 106 at the second side 102b of the substrate 102. The TSV 104 is coupled to a first wire 109 of a first wire level 108 past the second side 102b of the substrate, and a second wire 111 of a second wire level 110 past the first side 102a of the substrate 102. The TSV 104 is spaced from the STI region 106 by a semiconductor region 112 and a first insulative layer 126. The TSV 104 extends over a top surface of the first insulative layer 126 and under a bottom surface of the first insulative layer 126.

A resist protective oxide (RPO) 114 is on the second side 102b of the substrate 102. A contact etch stop layer (CESL) 116 extends over the RPO 114. A first ILD 118 is on the CESL 116 and surrounds the first wire 109 of the first wire level 108. A first high-k layer 122 is on the first side 102a of the substrate 102. In some embodiments, the first high-k layer 122 is or comprises a high-κ polymer. A passivation layer 124 is on the first high-k layer 122. A first insulative layer 126 is on the passivation layer 124 and extends along an inner sidewall of the substrate 102. A second insulative layer 128 covers an upper surface of the first insulative layer 126. A second ILD 120 covers the second insulative layer 128 and surrounds the second wire 111 of the second wire level 110. In some embodiments, the second insulative layer 128 has a top surface level with a top surface of the TSV 104.

Polymer residue 130 from the first high-k layer 122 extends along inner sidewalls of the passivation layer 124 and the substrate 102. If exposed to a seed layer tool used in the formation of the TSV 104, the polymer residue 130 may contaminate the seed layer tool. The first insulative layer 126 covers the polymer residue 130, preventing the contamination of the seed layer tool. The semiconductor region 112 is part of the substrate 102 and has substantially the same etch rate as the substrate 102. The spacing of the STI region 106 by the semiconductor region 112 results in a second etch not etching through the STI region 106, lowering the process time of the second etch. The lower process time protects the first insulative layer 126 covering the polymer residue 130, preventing the polymer residue 130 from contaminating the seed layer tool.

As shown in the top view 100b of FIG. 1B, the STI region 106 forms a continuous loop around the TSV 104. The semiconductor region 112 continuously surrounds the TSV 104, spacing the TSV 104 from the STI region 106. The first insulative layer 126 continuously surrounds the TSV 104 and spaces the semiconductor region 112 from the TSV 104.

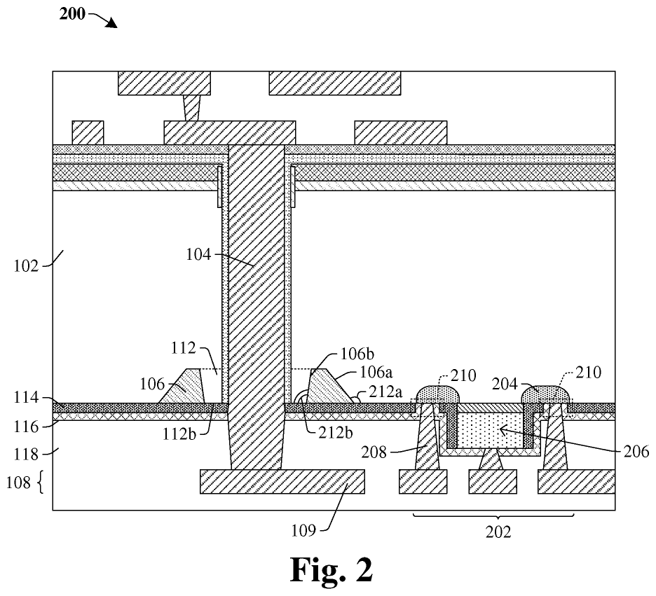

FIG. 2 illustrates a cross-sectional view 200 of additional embodiments of a TSV with an STI region surrounding and spaced from the TSV.

In some embodiments, a semiconductor device 202 is on the second side 102b of the substrate 102. The semiconductor device 202 has doped regions 204 (e.g., source/drain regions, or the like) extending into the substrate 102. The STI region 106 extends between the doped regions 204 and the TSV 104, insulating the doped regions 204 from the TSV 104. In some embodiments, the semiconductor device 202 further comprises a gate stack 206. The gate stack 206 and the doped regions 204 are coupled to the first wire level 108 by a plurality of contacts 208. The RPO 114 extends up sidewalls of the gate stack 206 and has openings 210 over the doped regions 204. A silicide layer is on a surface of the gate stack 206 and on the doped regions 204 in the openings 210. The CESL 116 conforms to the surface of the gate stack 206 and outer surfaces of the RPO 114.

The STI region 106 has an outer sidewall 106a at a first angle 212a to the second side 102b of the substrate 102. The STI region 106 further has an inner sidewall 106b at a second angle 212b to a bottom surface 112b of the semiconductor region 112. In some embodiments, the first angle 212a and the second angle 212b are both obtuse. An inner angle the outer sidewall 106a makes with the surface of the STI region 106 level with the second side 102b of the substrate 102 is acute. An inner angle the inner sidewall 106b makes with the surface of the STI region 106 level with the second side 102b of the substrate 102 is acute. In some embodiments, the first angle 212a and the second angle 212b are different.

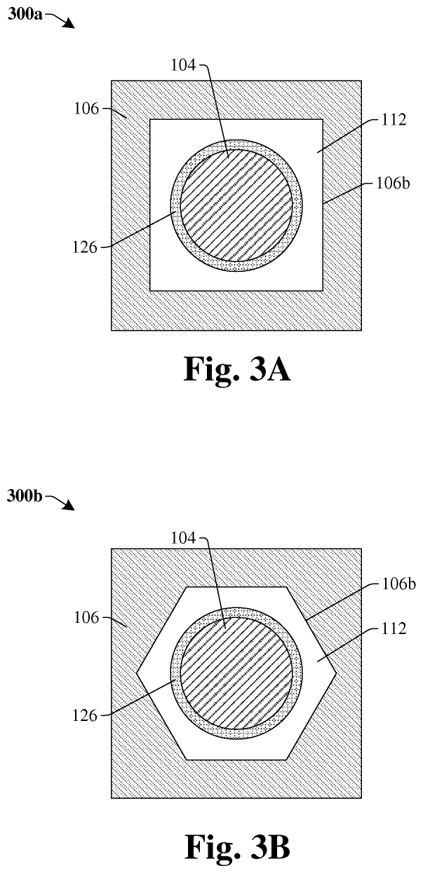

FIGS. 3A-3B illustrate top views 300a, 300b of additional embodiments of a TSV with an STI region surrounding and spaced from the TSV, where a semiconductor region between the STI region and the TSV has various shapes when viewed from a top view.

As shown in the top view 300a of FIG. 3A, an outer sidewall of the semiconductor region 112 may have a square profile when viewed from a top down perspective. That is, the etching of the STI region 106 may be performed around a square-shaped portion of a masking layer, leaving a semiconductor region 112 with a square profile remaining between inner sidewalls 106b of the STI region 106. As shown in the top view 300b of FIG. 3B, the outer sidewall of the semiconductor region 112 may have a hexagonal profile when viewed from a top down perspective. That is, the etching of the STI region 106 may be performed around a hexagonal-shaped portion of a masking layer, leaving a semiconductor region 112 with a hexagonal profile remaining between inner sidewalls 106b of the STI region 106. In the embodiments shown in FIGS. 3A and 3B, outer sidewalls of the TSV 104 and the first insulative layer 126 have a circular profile when viewed from a top down perspective. In other embodiments, the outer sidewalls of the TSV 104 and the first insulative layer 126 may have a square or hexagonal profile when viewed from a top down perspective.

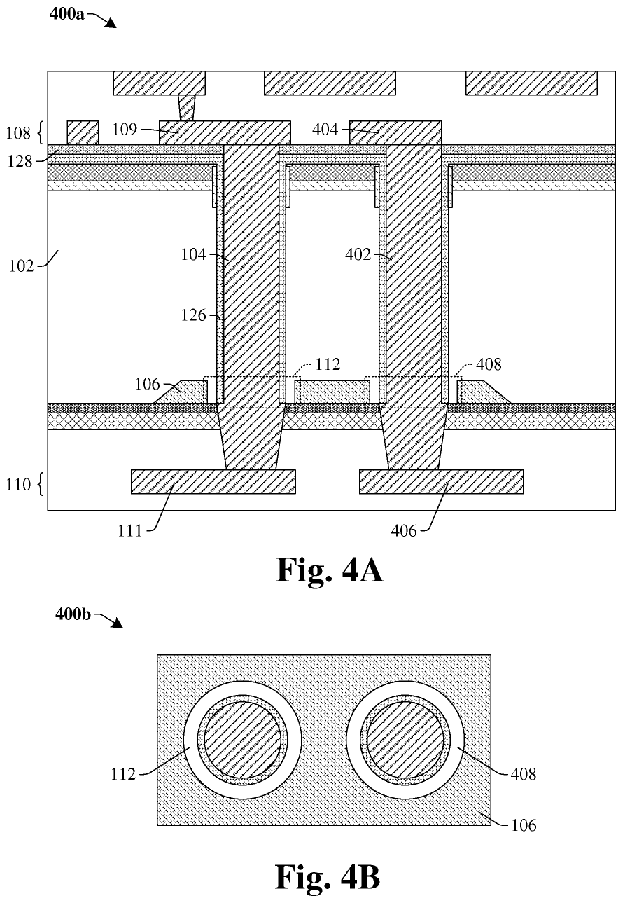

FIGS. 4A-4B illustrate a cross-sectional view and a top view of additional embodiments of a TSV with an STI region surrounding and spaced from the TSV, where multiple TSVs extend through the STI region.

As shown in the cross-sectional view 400a of FIG. 4A, in some embodiments, a second TSV 402 extends through the STI region 106 in addition to the first TSV 104. The second TSV 402 extends from a third wire 404 in the second wire level 110 to a fourth wire 406 in the first wire level 108. The second TSV 402 extends through a second semiconductor region 408. The second semiconductor region 408 is separated from the semiconductor region 112 by the STI region 106. The outer sidewall of the second semiconductor region 408 may have a circular, square, or hexagonal profile as shown in FIGS. 1B, 3A, and 3B. The first insulative layer 126 extends along inner sidewalls of the substrate 102 surrounding the first TSV 104 and the second TSV 402, and extends across an upper surface of the passivation layer 124 between the first TSV 104 and the second TSV 402. As shown in the cross-sectional view 400b of FIG. 4B, the outer sidewall of the second semiconductor region 408 may have the same profile as an outer sidewall of the semiconductor region 112.

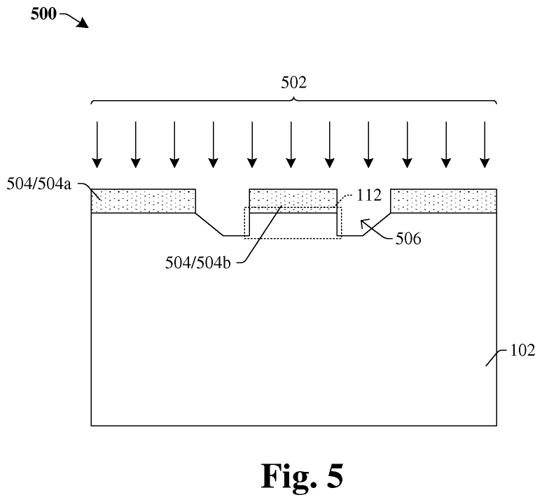

FIGS. 5-14 illustrate a series of cross-sectional views of some embodiments of a method of forming a TSV with an STI region surrounding and spaced from the TSV. Although FIGS. 5-14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in a top view 500 of FIG. 5, a first masking layer 504 is formed on the substrate 102. The substrate 102 may be any suitable type of substrate and/or may, for example, be a semiconductor wafer, one or more dies on a wafer, or any other suitable type of semiconductor body and/or epitaxial layers. In some embodiments, the substrate 102 is or comprises silicon, sapphire, the like, or any combination of the foregoing. The first masking layer 504 may, for example, be formed using chemical vapor deposition, physical vapor deposition, atomic layer deposition, a spin-on process, or the like. The first masking layer 504 is then patterned, thereby exposing portions of the substrate 102 corresponding to the STI region (see 106 of FIG. 1) to be formed hereafter. In some embodiments, the first masking layer 504 is or comprises a photoresist and/or the first masking layer 504 is patterned using photolithography. The first masking layer comprises a peripheral portion 504a and a central portion 504b. The peripheral portion 504a covers portions of the substrate 102 past the outer sidewalls of the STI region 106 (see FIG. 1A) to be formed hereafter. The central portion 504b covers the semiconductor region 112 of the substrate 102.

After the first masking layer 504 is patterned, a first etching process 502 is performed on the substrate 102 with the first masking layer 504 in place. The first etching process 502 removes portions of the substrate 102 exposed by the first masking layer 504, etching a first opening 506 into the substrate 102. The first opening 506 continuously surrounds the semiconductor region 112 of the substrate 102. In some embodiments, the first etching process 502 is a dry etching process. The first masking layer 504 is then removed.

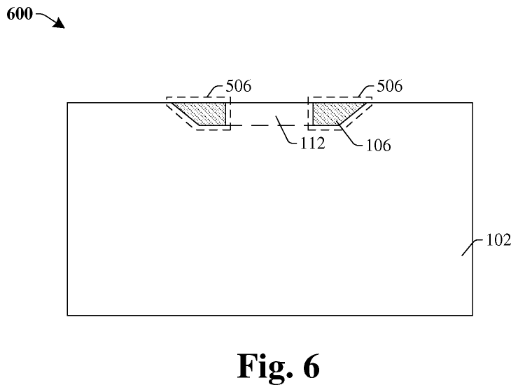

As shown in the cross-sectional view 600 of FIG. 6, the STI region 106 is formed in the first opening 506. In some embodiments, the STI region 106 is or comprises an insulative material such as silicon dioxide (SiO₂) or the like. In some embodiments, STI region 106 is formed using CVD, PVD, ALD, a thermal process, the like, or a combination of the foregoing to form a conformal insulative layer. A planarization process (e.g., a chemical-mechanical planarization (CMP) process) is then performed, removing portions of the conformal insulative layer over the second side 102b of the substrate 102.

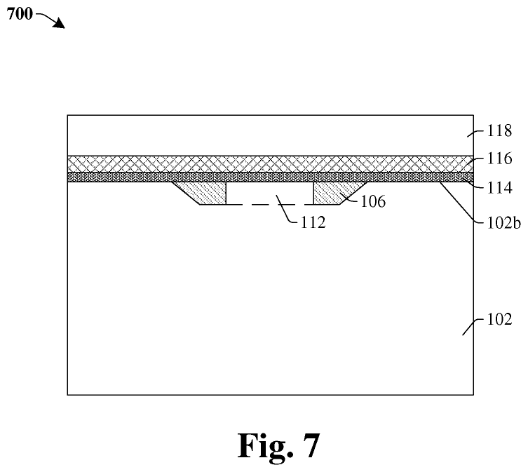

As shown in the cross-sectional view 700 of FIG. 7, the RPO 114, the CESL 116, and the second ILD 120 are formed on the second side 102b of the substrate 102. In some embodiments, the RPO 114, the CESL 116, and the second ILD 120 are formed using one or more of CVD, PVD, ALD, or the like. In some embodiments, the RPO 114 is or comprises an insulative material, such as silicon dioxide (SiO₂), silicon oxynitride, silicon nitride (Si₃N₄), or the like. In some embodiments, the CESL 116 is or comprises an insulative material, such as silicon nitride (Si₃N₄), or the like. In some embodiments, the second ILD 120 is or comprises an insulative material, such as silicon dioxide (SiO₂), silicon oxynitride, silicon nitride (Si₃N₄), or the like.

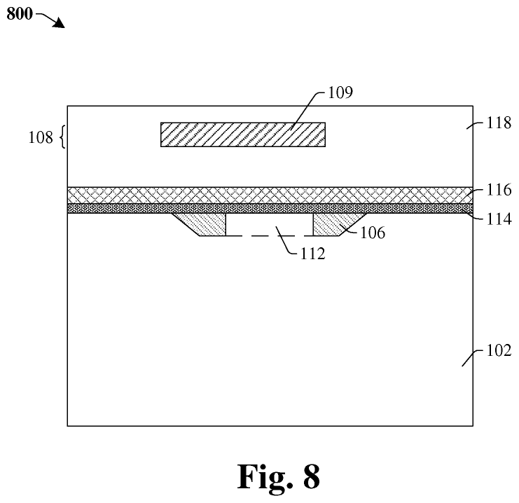

As shown in the cross-sectional view 800 of FIG. 8, the first wire level 108 is formed in the first ILD 118. The first wire level 108 comprises the first wire 109 overlying the semiconductor region 112. In some embodiments, the first wire 109 is formed using one or more of CVD, PVD, ALD, a damascene process, a planarization process, the like, or a combination of the foregoing. In some embodiments, the first wire 109 is or comprises a conductive material, such as copper (Cu), tungsten (W), aluminum (Al), titanium nitride (TiN₂), or the like.

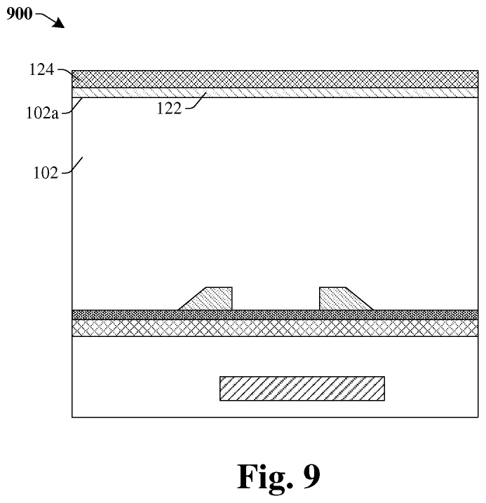

As shown in the cross-sectional view 900 of FIG. 9, the first high-k layer 122 and the passivation layer 124 are formed on the first side 102a of the substrate 102. In some embodiments, the first high-k layer 122 and the passivation layer 124 are formed using one or more of CVD, PVD, ALD, or the like. In some embodiments, the first high-k layer 122 is or comprises a high-κ material, such as hafnium dioxide (HfO₂), zirconium dioxide (ZrO₂), hafnium silicate (HfSO₄), zirconium silicate (ZrSO₄), a high-κ polymer, or the like. In some embodiments, the passivation layer 124 is or comprises an insulative material, such as silicon dioxide (SiO₂), undoped silicate glass (USG), or the like.

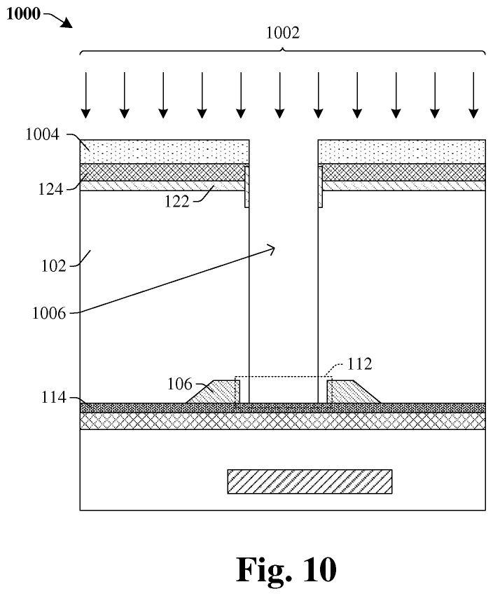

As shown in the cross-sectional view 1000 of FIG. 10, a third masking layer 1004 is formed on the passivation layer 124. The third masking layer 1004 may, for example, be formed using CVD, PVD, ALD, a spin-on process, or the like. The third masking layer 1004 is then patterned, thereby exposing a portion of the passivation layer 124 directly overlying the semiconductor region 112 between inner sidewalls of the STI region 106. In some embodiments, the third masking layer 1004 is or comprises a photoresist and/or the third masking layer 1004 is patterned using photolithography.

After the third masking layer 1004 is patterned, a third etching process 1002 is performed on the passivation layer 124, the first high-k layer 122, and the substrate 102 with the third masking layer 1004 in place. The third etching process 1002 removes portions of the passivation layer 124, the first high-k layer 122, and the substrate 102 exposed by the third masking layer 1004, etching a third opening 1006 into the substrate 102 and through the semiconductor region 112, exposing the RPO 114. In some embodiments, the third etching process 1002 is a dry etching process. The third masking layer 1004 is then removed.

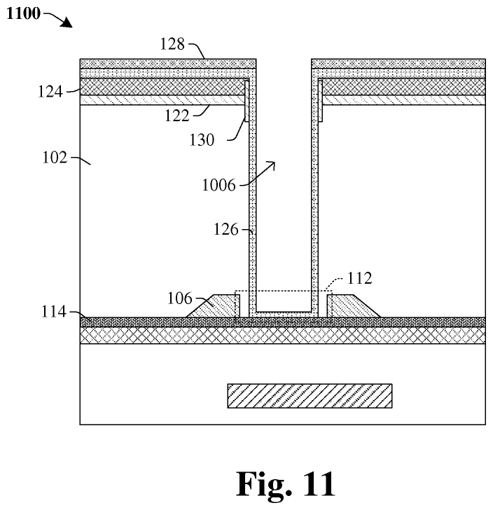

As shown in in the cross-sectional view 1100 of FIG. 11, a first insulative layer 126 and a second insulative layer 128 are deposited over the passivation layer 124 and within the third opening 1006. In some embodiments, when the first high-k layer 122 comprises a high-κ polymer, polymer residue 130 may form on the sidewalls of the substrate 102, the first high-k layer 122, and the passivation layer 124 during the third etching process 1002. The polymer residue 130 may contaminate the tools used in subsequent etching and ALD steps. The first insulative layer 126 covers the inner sidewalls of the third opening, sealing the polymer residue 130 between the substrate 102 and the first insulative layer 126. In some embodiments, the second insulative layer 128 does not line inner sidewalls of the first insulative layer 126 due to the deposition process used to form the second insulative layer having poor step coverage. In some embodiments, the first insulative layer 126 is or comprises silicon dioxide (SiO₂) or the like. In some embodiments, the second insulative layer 128 is or comprises silicon nitride (Si₃N₄) or the like. The first insulative layer 126 is a different material than the second insulative layer 128.

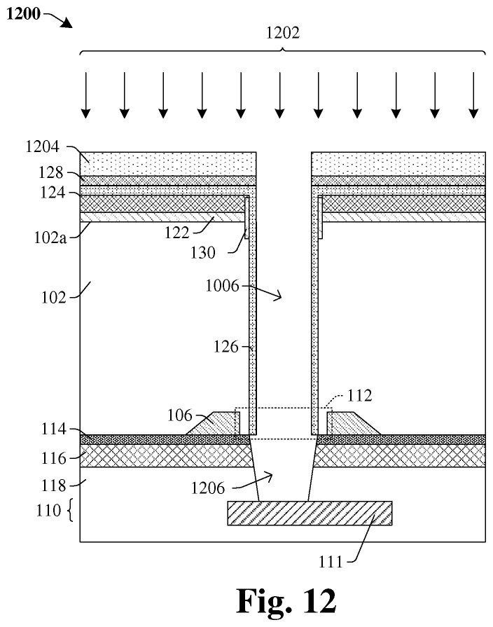

As shown in in the cross-sectional view 1200 of FIG. 12, a fourth masking layer 1204 is formed on the second insulative layer 128. The fourth masking layer 1204 may, for example, be formed using CVD, PVD, ALD, a spin-on process, or the like. The fourth masking layer 1404 is then patterned, thereby exposing the third opening 1006. In some embodiments, the fourth masking layer 1204 is or comprises a photoresist and/or the fourth masking layer 1204 is patterned using photolithography.

After the fourth masking layer 1204 is formed, a fourth etching process 1202 is performed on the substrate 102. The fourth masking layer 1204 covers upper surfaces of the first insulative layer 126, and the second insulative layer 128. The fourth etching process 1202 forms the fourth opening 1206 beneath the third opening 1006. The fourth etching process 1202 has a lower etch rate through the material of the second insulative layer 128 than the etch rate of the fourth etching process 1202 through the materials of the RPO 114 and the first ILD 118. The fourth opening 1206 extends through the RPO 114, the CESL 116, and the first ILD 118 to reach the first wire 109 of the first wire level 108. The semiconductor region 112 remaining in the substrate 102 around the third opening 1006 results in the fourth etching process 1202 not beginning at the STI region 106 and instead beginning at the RPO 114, lowering the process time of the fourth etching process 1202. The lower process time of the fourth etching process 1202 results in the second insulative layer 128 remaining over the substrate 102 and the first insulative layer 126 remaining over the inner sidewalls of the third opening 1006, preventing the polymer residue 130 from becoming exposed during the etch.

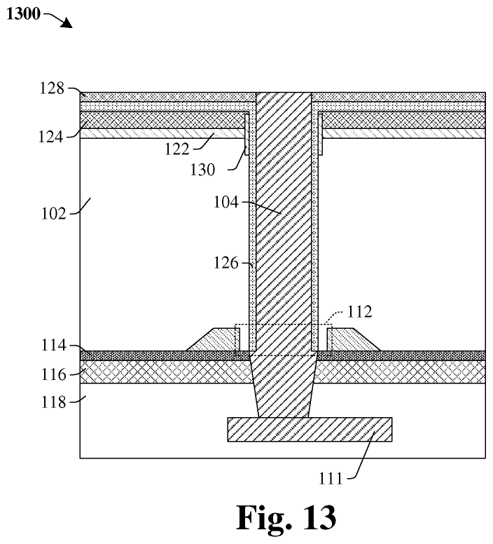

As shown in in the cross-sectional view 1300 of FIG. 13, the TSV 104 is formed in the third opening (see 1006 of FIG. 12) and the fourth opening (see 1206 of FIG. 12). In some embodiments, the TSV 104 is formed by forming a seed layer along inner sidewalls of the second insulative layer 128, the first ILD 118, and the CESL 116. The polymer residue 130 is separated from the TSV 104 by the first insulative layer 126 and the second insulative layer 128, protecting the tool used in the formation of the seed layer from contamination by the polymer residue 130. After the seed layer is formed, the third opening (see 1006 of FIG. 12) and the fourth opening (see 1206 of FIG. 12) are filled with a conformal conductive layer. A planarization process is subsequently performed to remove portions of the conformal conductive layer that are above an upper surface of the second insulative layer 128, leaving the TSV 104 in the substrate 102. In some embodiments, the TSV is or comprises a conductive metal, such as copper (Cu) or the like.

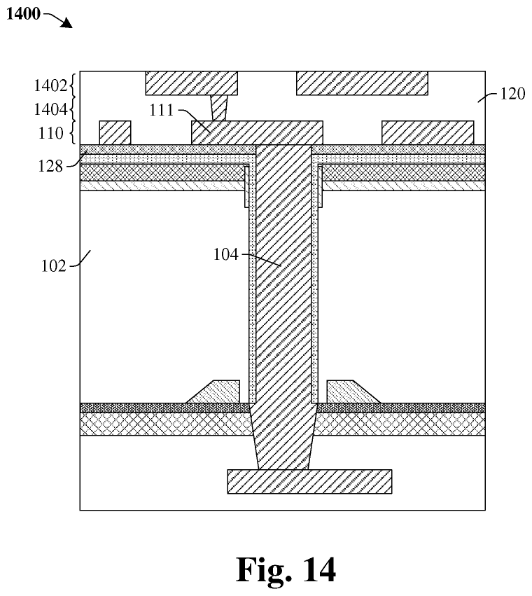

As shown in in the cross-sectional view 1400 of FIG. 14, the second wire level 110 is formed over the second insulative layer 128 and the TSV 104. The second wire level 110 comprises the second ILD 120 and the second wire 111 coupled to the TSV 104. In some embodiments, the second wire level 110 may be coupled to additional wire levels 1402 by additional via levels 1404 overlying the second wire level 110. In some embodiments, the second wire 111 is formed using one or more of CVD, PVD, ALD, a damascene process, a planarization process, the like, or a combination of the foregoing. In some embodiments, the second wire 111 is or comprises a conductive material, such as copper (Cu), tungsten (W), aluminum (Al), titanium nitride (TiN₂), or the like.

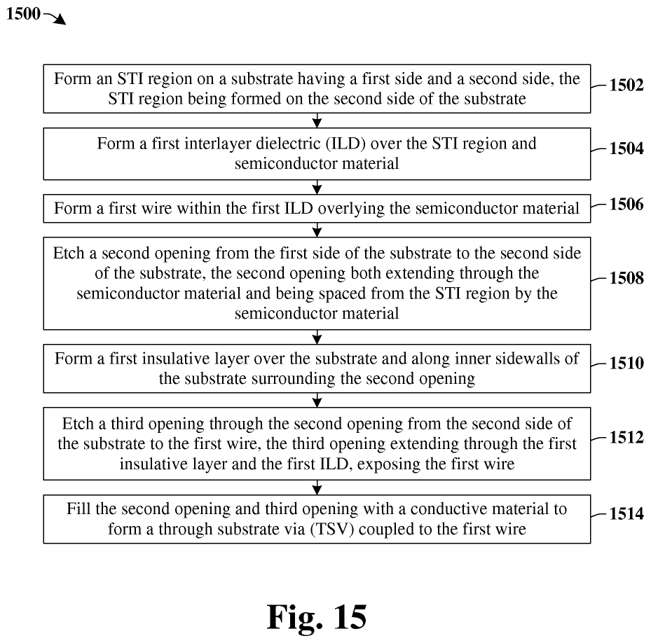

FIG. 15 illustrates a flowchart of some embodiments of a method of forming a TSV with an STI region surrounding and spaced from the TSV. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1502, an STI region is formed around a semiconductor region on a substrate having a first side and a second side, the STI region being formed on the second side of the substrate. See, for example, FIG. 6.

At 1504, a first ILD is formed over the STI region and semiconductor region. See, for example, FIG. 7.

At 1506, a first wire is formed within the first ILD overlying the semiconductor material. See, for example, FIG. 8.

At 1508, a second opening is etched from the first side of the substrate to the second side of the substrate, the second opening both extending through the semiconductor material and being spaced from the STI region by the semiconductor material. See, for example, FIG. 10.

At 1510, a first insulative layer is formed over the substrate and along inner sidewalls of the substrate surrounding the second opening. See, for example, FIG. 11.

At 1512, a third opening is etched through the second opening from the first side of the substrate to the second side of the substrate, the third opening extending through the first insulative layer and the first ILD, exposing the first wire. See, for example, FIG. 12.

At 1514, the second opening and the third opening are filled with a conductive material to form a through substrate via (TSV) coupled to the first wire. See, for example, FIG. 13.

Some embodiments relate to an integrated device, including a substrate having a first side and a second side opposite the first side, the substrate being a first material; a first wire level on the first side of the substrate and having a first wire; a second wire level on the second side of the substrate and having a second wire; a through-substrate via (TSV) extending from the first wire to the second wire through the substrate; a shallow trench isolation (STI) region surrounding the TSV at the second side of the substrate; and a semiconductor region between the STI region and the TSV, the semiconductor region comprising the first material.

Other embodiments relate to an integrated device, including: a substrate having a first side and a second side opposite the first side; a through-substrate via (TSV) extending from the first side to the second side; a shallow trench isolation (STI) region forming a continuous loop surrounding the TSV at the second side; and a first insulative layer spacing the TSV from the substrate, where the first insulative layer is separated from the STI region.

Yet other embodiments relate to a method of forming an integrated device, including forming an STI region on a substrate having a first side and a second side, the STI region being formed on the second side of the substrate and forming a continuous loop around a semiconductor region; etching a first opening from the first side of the substrate to the second side of the substrate, the first opening both extending through the semiconductor region and being spaced from the STI region by the semiconductor region; and filling the first opening with a conductive material to form a through substrate via (TSV).

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate comprising a first side and a second side opposite the first side, the substrate comprising a first material;
a first wire level on the second side of the substrate and comprising a first wire;
a second wire level on the first side of the substrate and comprising a second wire;
a through-substrate via (TSV) extending from the first wire to the second wire through the substrate;
a shallow trench isolation (STI) region surrounding the TSV at the second side of the substrate; and
a semiconductor region between the STI region and the TSV, the semiconductor region comprising the first material.

2. The integrated device of claim 1, wherein the semiconductor region has a circular outer sidewall when viewed from a top down perspective.

3. The integrated device of claim 1, wherein the semiconductor region has a rectangular outer sidewall when viewed from a top down perspective.

4. The integrated device of claim 1, wherein the semiconductor region has a hexagonal outer sidewall when viewed from a top down perspective.

5. The integrated device of claim 1, further comprising a first insulative layer extending along inner sidewalls of the substrate from the first side to the second side, wherein the TSV extends over a top surface of the first insulative layer and under a bottom surface of the first insulative layer.

6. The integrated device of claim 5, further comprising a second insulative layer overlying the first insulative layer and extending along an outer sidewall of the TSV, the second insulative layer comprising a top surface level with a top surface of the TSV.

7. The integrated device of claim 1, wherein the STI region has an outer sidewall facing away from the TSV and an inner sidewall facing towards the TSV, wherein the outer sidewall of the STI region has a first angle formed between the outer sidewall and the second side of the substrate that is obtuse, wherein the inner sidewall of the STI region has a second angle formed between the inner sidewall and a bottom surface of the semiconductor region, and wherein the second angle is obtuse.

8. An integrated device, comprising:
a substrate comprising a first side and a second side opposite the first side;
a through-substrate via (TSV) extending from the first side to the second side;
a shallow trench isolation (STI) region forming a continuous loop surrounding the TSV at the second side; and
a first insulative layer spacing the TSV from the substrate, where the first insulative layer is separated from the STI region.

9. The integrated device of claim 8, further comprising:
a resist protective oxide (RPO) layer on the second side of the substrate;
a contact etch stop layer (CESL) on the RPO layer;
an interlayer dielectric (ILD) on the CESL; and
a wire level in the ILD comprising a first wire, wherein the TSV extends through the RPO layer, the CESL, and the ILD to the first wire of the wire level.

10. The integrated device of claim 8, further comprising:
a first high-k layer on the first side of the substrate comprising a first material; and
a passivation layer on the first high-k layer, wherein the first material of the first high-k layer extends over inner sidewalls of the substrate and the passivation layer, and wherein the first insulative layer spaces the first material on the inner sidewalls of the substrate and the passivation layer from the TSV.

11. The integrated device of claim 10, further comprising:
a second insulative layer overlying the first high-k layer, the passivation layer, and the first insulative layer, wherein the second insulative layer is a different material from the first insulative layer.

12. The integrated device of claim 8, further comprising:
a semiconductor device on the second side of the substrate, the semiconductor device having doped regions within the substrate that are spaced from the TSV by the STI region.

13. The integrated device of claim 8, further comprising:
a second TSV extending from the first side to the second side, wherein the STI region forms a second continuous loop surrounding the second TSV, and wherein the first insulative layer further spaces the second TSV from the substrate and extends across the first side of the substrate between the TSV and the second TSV.

14. A method of forming an integrated device, comprising:
forming an STI region on a substrate having a first side and a second side, the STI region being formed on the second side of the substrate and forming a continuous loop around a semiconductor region;
etching a first opening from the first side of the substrate to the second side of the substrate, the first opening both extending through the semiconductor region and being spaced from the STI region by the semiconductor region; and
filling the first opening with a conductive material to form a through substrate via (TSV).

15. The method of claim 14, further comprising:
forming a first wire level on the second side of the substrate before the first opening is etched; and
etching a second opening at a bottom of the first opening, such that etching the second opening exposes a first wire of the first wire level; and
forming a second wire level on the second side of the substrate after the TSV is formed, such that the TSV is coupled to a second wire of the second wire level.

16. The method of claim 14, further comprising:
forming a resist protective oxide (RPO) on the second side of the substrate after forming the STI region around the semiconductor region;
forming a contact etch stop layer (CESL) on the RPO;
forming a first wire level in an interlayer dielectric (ILD); and
after the first opening is formed, etching a second opening at a bottom of the first opening, the second opening extending through the RPO, the CESL, and the ILD to reach the first wire level.

17. The method of claim 16, wherein etching the first opening comprises:
performing a first etch, forming the first opening extending through the substrate to the RPO;
forming a first insulative layer lining the first opening;
forming a second insulative layer overlying the first insulative layer; and
performing a second etch, the second etch removing portions of the RPO, CESL, and ILD directly between the first opening and the first wire level and forming the second opening.

18. The method of claim 17, wherein the second etch has a lower etch rate through a material of the second insulative layer than an etch rate of the second etch through materials of the ILD and the RPO.

19. The method of claim 14, wherein a sidewall of the STI region forming the continuous loop surrounding the semiconductor region has a circular profile when viewed from a top down perspective.

20. The method of claim 14, wherein the STI region forms a second continuous loop around a second semiconductor region, and further comprising:
etching a second opening through the substrate concurrently with the etching of the first opening, wherein the second opening extends through the substrate and the second semiconductor region;
forming a first insulative layer lining the first opening and the second opening, extending between the first opening and the second opening on the first side of the substrate; and
filling the second opening with the conductive material to form a second TSV.
